(19) United States
(12) Patent Application Publication
(10) Pub. No.: US 2006/0096634 A1
(43) Pub. Date: May 11, 2006

(54) Junction for photovoltaic cells, optical sensors or the like

(76) Inventor: Marco Pizzi, Torino (IT)

Correspondence Address: NIXON & VANDERHYE, PC, 901 NORTH GLEBE ROAD, 11TH FLOOR, ARLINGTON, VA, 22203, US

(21) Appl. No.: 10/551,045

(22) PCT Filed: Dec. 23, 2003
(86) PCT No.: PCT/IB03/06283

§ 371 Date: Dec. 2, 2005

(30) Foreign Application Priority Data
Mar. 27, 2003 (IT) TO2003A000228

(51) Int. Cl. H01L 31/00

(52) U.S. Cl. 136/262; 136/252; 136/261; 438/95; 439/93

(57) ABSTRACT

A junction for photovoltaic cells, optical sensors or the like comprises a microporous or nanoporous silicon layer and a metal or semiconductor layer deposited so as to fill at least partially the pores of the silicon layer.

The present invention relates to junctions for photovoltaic cells, optical sensors or the like.

The photovoltaic effect is the conversion of electromagnetic radiation (especially light) into electric current, which occurs in some materials, such as silicon and germanium, known as “semiconductors”.

Devices operating on the basis of said principle are known as “photovoltaic cells”. They are currently used for instance as energy supply for calculating machines and solar energy watches, and in the field of nuclear physics as photon detectors (gamma rays). On artificial satellite large solar panels supply energy to on-board instruments.

The conductive capacity of semiconductors strongly depends on their purity and can be increased by introducing impurities into the latter (doping). By placing close to one another two semiconductors doped so that one has an excess of positive charges (known as holes) and the other one an excess of negative charges, a p-n junction is obtained. The semiconductor absorbs part of the photons belonging to the light illuminating it. When a photon is absorbed, its energy releases an electron (which can move within the semiconductor) and generates at the same time a positive hole. The electron and the hole are spontaneously separated by the electronic field of the junction and are stored in two opposite areas so as to generate a potential difference at the ends of the device. By connecting said two ends to a circuit electric current is obtained. The photovoltaic cell is the device that can convert the energy of light radiations directly into electric energy. It basically consists of two thin layers of semiconductor material (crystalline or amorphous silicon or other substances): a n-type layer (which tends to collect electrons), and a p-type layer (which tends to collect positive charges or holes). The photovoltaic cell is usually equipped with an antireflection coating and with two electric contacts, an upper one and a lower one.

During operation, in the contact area (junction) between the two semiconductors there is an electric field due to the different nature of said two materials. When the contact area is struck by sunlight, i.e. by photons, electrons (the outer ones in silicon atoms) are “mobilized” and pushed into layer n by the electric field. Every electron getting released gives simultaneously rise to a positive charge which—still due to the electric field—is pushed into layer p. The connection of both layers to an outer circuit results in a circulation of electrons, i.e. in a direct electric current, between n and p.

Solar cells or optical sensors with porous silicon have also been proposed, using so-called “Schottky” junctions, for instance with gold or aluminum.

The present invention aims at carrying out a junction of this type, which is able to highly increase cell efficiency or to obtain a particularly sensitive sensor.

In order to achieve said aim, the junction according to the present invention is characterized in that it has the features referred to in the appended claim 1.

Thanks to said features the surface of the junction is greatly increased, so as to obtain a high increase in cell efficiency.

The invention will now be described with reference to the accompanying drawings, provided as a mere non-limiting example, in which:

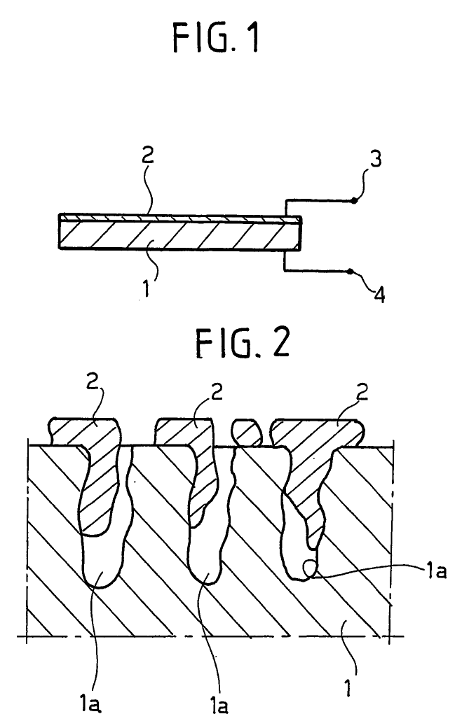

FIG. 1 is a schematic view of a silicon-metal junction according to the prior art,

FIG. 2 is a magnified scale view of a detail of FIG. 1 modified according to the teachings of the present invention,

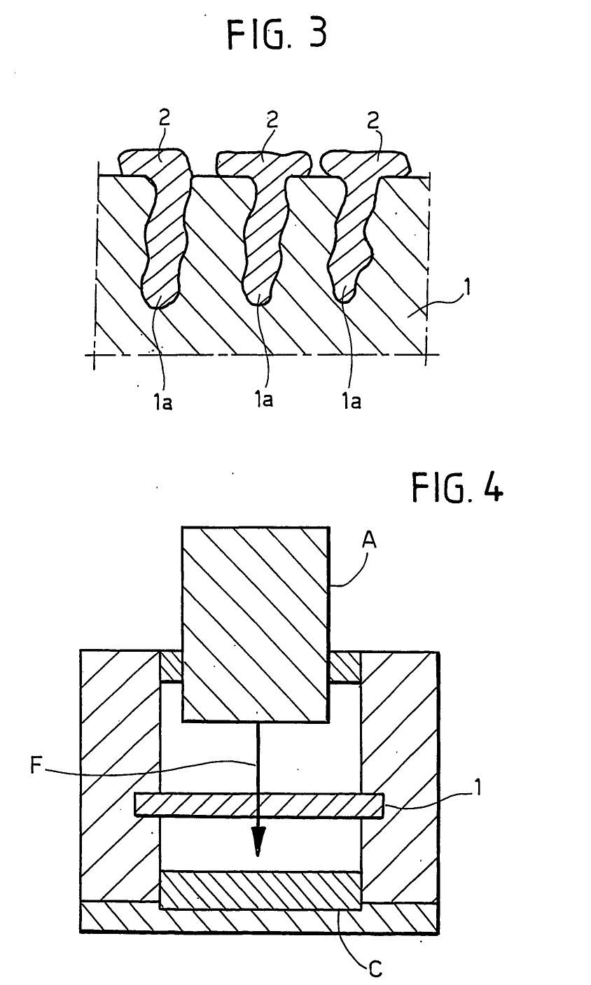

FIG. 3 shows a further embodiment of the invention, and

FIG. 4 shows a further embodiment.

FIG. 1 shows schematically a junction comprising a silicon layer 1 and a metal layer 2, for instance gold or aluminum. According to a technique known per se, the silicon layer 1 has a porous structure whose pores have a micrometric or nanometric size (microporous or nanoporous silicon). According to the prior art, the metal is deposited by thermal evaporation onto the silicon layer 1. As a consequence of said application the metal does not penetrate into silicon pores and the useful junction is still the one on the surface. The two layers are connected to two electrodes 3, 4.

According to the invention, techniques known per se, for instance sol gel deposition techniques or more generally so-called CSD techniques (“Chemical Solution Deposition”), are used to let the metal 2 penetrate into the pores of microporous or nanoporous silicon, so as to fill them partially (FIG. 2) or completely (FIG. 4).

An object of the present patent is also a new technique for filling silicon pores: porous silicon is usually obtained by anodization in a bath of hydrofluoric acid. Typical currents for obtaining nanoporous silicon are of about 10 mA/cm². After a normal anodization step, whose duration depends on the porous thickness desired for silicon, a solution of gold chloride is introduced into the bath. Gold reduces on silicon: the presence of holes simplifies the penetration of gold chloride into the pores where gold deposits. Reduction occurs spontaneously but can be favored by inverting cell polarity during the final step of the process. Gold chloride is just an example, though other solutions also with other metals are possible.

The phenomenon can be further favored by making the substrate 1 completely porous (FIG. 4), with through pores, and by arranging a cathode C and anode A after and before said substrate, thus forcing metal ions (arrow F) to go through it. A part of them reduces in the porous substrate, which can be kept at the same potential as the cathode or at a floating potential.

Thus, every square centimeter of silicon corresponds to a few useful square meters of junction.

The same principle can obviously apply to electromagnetic radiations having different wavelength, for instance for thermophotovoltaic applications, by suitably choosing materials depending on the relevant frequency range.

According to a further feature of the invention, in order to increase at the same time surface transmittance and conductivity, silicon pores can be filled with the optimal junction material and then an ITO layer (Indium Tin Oxide) can be deposited onto the surface.

Obviously, though the basic idea of the invention remains the same, construction details and embodiments can widely vary with respect to what has been described and shown by mere way of example, however without leaving the framework of the present invention.

1. Junction, in particular for photovoltaic cells, optical sensors or the like, comprising a layer made of a first microporous or nanoporous material chosen among silicon, gallium antimonide or gallium arsenide, and a layer made of a second material chosen between a metal or a semiconductor, deposited onto the layer made of said first porous material, characterized in that the pores of the layer made of said first material are at least partially filled with the aforesaid second material.

2. Junction according to claim 1, characterized in that the second material is deposited into the pores of the first material by means of electrochemical deposition techniques.

3. Junction according to claim 1, characterized in that an ITO layer is deposited above the layer made of the second material.

4. Photovoltaic cell, characterized in that it comprises a junction according to claim 1.

5. Cell according to claim 4, characterized in that the first material is porous silicon and in that the surface of porous silicon is covered with metal nanoclusters, which carry out at the same time the Shottky junction and the conductive layer required for transmitting the general charge to exploiting means.

6. Process for carrying out a junction, particularly for photovoltaic cells, optical sensors or the like, in which a layer made of a first microporous or nanoporous material chosen among silicon, gallium antimonide and gallium arsenide, and a layer made of a second material chosen between a metal and a semiconductor, deposited onto the layer of said first porous material, are prepared, characterized in that the pores of the layer made of said first material are at least partially filled with the aforesaid second material.

7. Process according to claim 6, characterized in that said first material is obtained by anodization in a bath of hydrofluoric acid.

8. Process according to claim 7, characterized in that said first porous material is obtained by anodization, with an electric current of about 10 mA/cm2, and in that after a normal anodization step a solution of a metal compound is introduced into the bath, for instance a gold chloride, which penetrates into the pores of the first porous material and gives rise to the reduction of the metal, gold for instance, on the first material.

9. Process according to claim 8, characterized in that metal reduction is favored by inverting cell polarity during the final step of the process.

10. Process according to claim 9, characterized in that the substrate made of the first material is made completely porous, with through pores, and a cathode and an anode are arranged after and before the substrate, thus forcing metal ions to go through it, so that a part of them reduces in the porous substrate, which can be kept at the same potential as the cathode or at a floating potential.
